(19) United States
(12) Patent Application Publication
(10) Pub. No.: US 2015/0340468 A1
(43) Pub. Date: Nov. 26, 2015

(54) RECESSED CHANNEL FIN DEVICE WITH RAISED SOURCE AND DRAIN REGIONS

(71) Applicant: GLOBALFOUNDRIES Inc., Grand Cayman (KY)

(72) Inventors: Kwan-Yong Lim, Niskayuna, NY (US); Min Gyu Sung, Latham, NY (US); Jody A. Fronheiser, Delmar, NY (US); Christopher M. Prindle, Poughkeepsie, NY (US)

(73) Assignee: GLOBALFOUNDRIES Inc., Grand Cayman (KY)

(21) Appl. No.: 14/283,721

(22) Filed: May 21, 2014

(51) Int. Cl. H01L 29/66; H01L 29/78

(52) U.S. Cl. CPC H01L 29/66795; H01L 29/66545; H01L 29/7851; H01L 29/7848

(57) ABSTRACT

A method includes forming at least one fin in a semiconductor substrate. A sacrificial gate structure is formed around a first portion of the at least one fin. Sidewall spacers are formed adjacent the sacrificial gate structure. The sacrificial gate structure and spacers expose a second portion of the at least one fin. An epitaxial material is formed on the exposed second portion. At least one process operation is performed to remove the sacrificial gate structure and thereby define a gate cavity between the spacers that exposes the first portion of the at least one fin. The first portion of the at least one fin is recessed to a first height less than a second height of the second portion of the at least one fin. A replacement gate structure is formed within the gate cavity above the recessed first portion of the at least one fin.

### BACKGROUND OF THE INVENTION

1. Field of the Invention

The present disclosure generally relates to the fabrication of semiconductor devices, and, more particularly, to a recessed channel fin device with raised source and drain regions.

2. Description of the Related Art

In modern integrated circuits, such as microprocessors, storage devices and the like, a very large number of circuit elements, especially transistors, are provided and operated on a restricted chip area. In integrated circuits fabricated using metal-oxide-semiconductor (MOS) technology, field effect transistors (FETs) (both NMOS and PMOS transistors) are provided that are typically operated in a switching mode. That is, these transistor devices exhibit a highly conductive state (on-state) and a high impedance state (off-state). FETs may take a variety of forms and configurations. For example, among other configurations, FETs may be either so-called planar FET devices or three-dimensional (3D) devices, such as FinFET devices.

A field effect transistor (FET), irrespective of whether an NMOS transistor or a PMOS transistor is considered, and irrespective of whether it is a planar or 3D FinFET device, typically comprises doped source/drain regions that are formed in a semiconductor substrate that are separated by a channel region. A gate insulation layer is positioned above the channel region and a conductive gate electrode is positioned above the gate insulation layer. The gate insulation layer and the gate electrode may sometimes be referred to as the gate structure for the device. By applying an appropriate voltage to the gate electrode, the channel region becomes conductive and current is allowed to flow from the source region to the drain region. In a planar FET device, the gate structure is formed above a substantially planar upper surface of the substrate. In some cases, one or more epitaxial growth processes are performed to form epitaxial (epi) semiconductor material in recesses formed in the source/drain regions of the planar FET device. In some cases, the epi material may be formed in the source/drain regions without forming any recesses in the substrate for a planar FET device, or the recesses may be overfilled, thus forming raised source/drain regions. The gate structures for such planar FET devices may be manufactured using so-called “gate-first” or “replacement gate” (gate-last) manufacturing techniques.

To improve the operating speed of FETs, and to increase the density of FETs on an integrated circuit device, device designers have greatly reduced the physical size of FETs over the years. More specifically, the channel length of FETs has been significantly decreased, which has resulted in improving the switching speed of FETs. However, decreasing the channel length of a FET also decreases the distance between the source region and the drain region. In some cases, this decrease in the separation between the source and the drain makes it difficult to efficiently inhibit the electrical potential of the source region and the channel from being adversely affected by the electrical potential of the drain. This is sometimes referred to as a so-called short channel effect, wherein the characteristic of the FET as an active switch is degraded.

In contrast to a FET, which has a planar structure, a so-called FinFET device has a three-dimensional (3D) structure. FIG. 1A is a side view of an illustrative prior art FinFET semiconductor device 100 that is formed above a semiconductor substrate 105. In this example, the FinFET device 100 includes three illustrative fins 110, a gate structure 115, sidewall spacers 120, and a gate cap 125. The gate structure 115 is typically comprised of a layer of insulating material (not separately shown), e.g., a layer of high-k insulating material or silicon dioxide, and one or more conductive material layers (e.g., metal and/or polysilicon) that serve as the gate electrode for the device 100. The fins 110 have a three-dimensional configuration. The portions of the fins 110 covered by the gate structure 115 is the channel region of the FinFET device 100. An isolation structure 130 is formed between the fins 110. In a conventional process flow, the portions of the fins 110 that are positioned outside of the spacers 120, i.e., in the source/drain regions of the device 100, may be increased in size or even merged together by performing one or more epitaxial growth processes. The process of increasing the size of the fins 110 in the source/drain regions of the device 100 is performed to reduce the resistance of source/drain regions and/or make it easier to establish electrical contact to the source/drain regions.

FIG. 1B illustrates a cross-sectional view of the finFET device 100. The fins 110 shown in FIG. 1A are densely-spaced fins. Additional isolated fins 135 are illustrated representing a different region of the substrate 105. For example, the densely-spaced fins 110 may be part of a logic device or SRAM NFET, while the isolated fins 135 may be part of an SRAM PFET. During an epi material growth process, the growth starts in the direction of a (111) crystallographic plane of the substrate 105. In the case of the densely spaced fins 110, the epi regions can grow between the fins 110 and merge to form a horizontal surface. Further growth from the horizontal surface occurs in a direction corresponding to a (100) plane of the substrate. Growth occurs much faster in a (100) plane as compared to a (111) plane, thus resulting in a merged epi structure 140 above the densely-spaced fins 110 and discrete epi structures 145 above the isolated fins 135.

A device with the merged epi structure 140 can have different device characteristics as compared to a device with the discrete epi structure 145. For example, the resistance of the device may be higher for the device with the merged epi structure 140. Due to the higher topology of the merged epi structure 140, the contact etches terminate differently, and the contact structures have different sizes. This size difference results in a difference in resistance. In addition, the fins 110 may be associated with separate devices, and the merged epi structure 140 may cause a short circuit between the fins 110 of separate devices, which may destroy their functionality.

The present disclosure is directed to various methods and resulting devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming semiconductor devices. A method includes forming at least one fin in a semiconductor substrate. A sacrificial gate structure is formed around a first portion of the at least one fin. Sidewall spacers are formed adjacent the sacrificial gate structure. The sacrificial gate structure and spacers expose a second portion of the at least one fin. An epitaxial material is formed on the exposed second portion of the at least one fin. At least one process operation is performed to remove the sacrificial gate structure and thereby define a gate cavity between the spacers that exposes the first portion of the at least one fin. The first portion of the at least one fin is recessed to a first height less than a second height of the second portion of the at least one fin. A replacement gate structure is formed within the gate cavity above the recessed first portion of the at least one fin.

One illustrative device disclosed herein includes, among other things, at least one fin having a first height. Epitaxial material is disposed on tip portions of the at least one fin in source/drain regions of the at least one fin. A channel region of the at least one fin is defined between the source and drain regions and has a second height less than the first height. A gate electrode structure is formed above the channel region.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1B schematically depict an illustrative prior art finFET device; and

FIGS. 2A-2B and 3A-3G depict various methods disclosed herein of forming a finFET device.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to various methods of forming a finFET device with raised epitaxial source/drain regions without causing merging of the epi material above densely-spaced fins and the resulting semiconductor devices. As will be readily apparent to those skilled in the art upon a complete reading of the present application, the present method is applicable to a variety of devices, including, but not limited to, logic devices, memory devices, etc. With reference to the attached figures, various illustrative embodiments of the methods and devices disclosed herein will now be described in more detail.

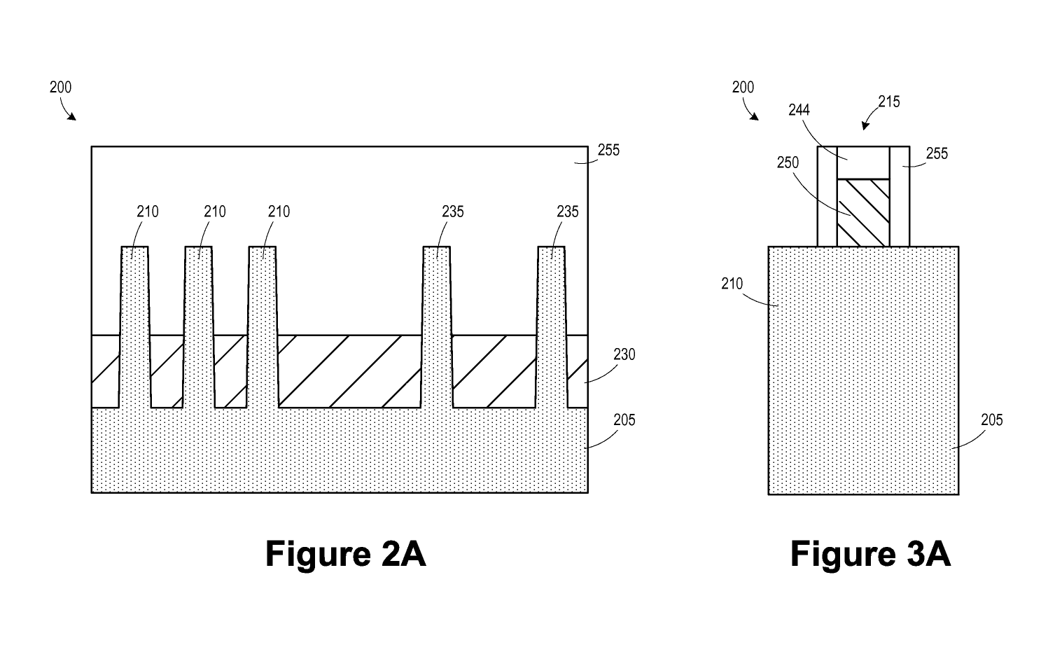

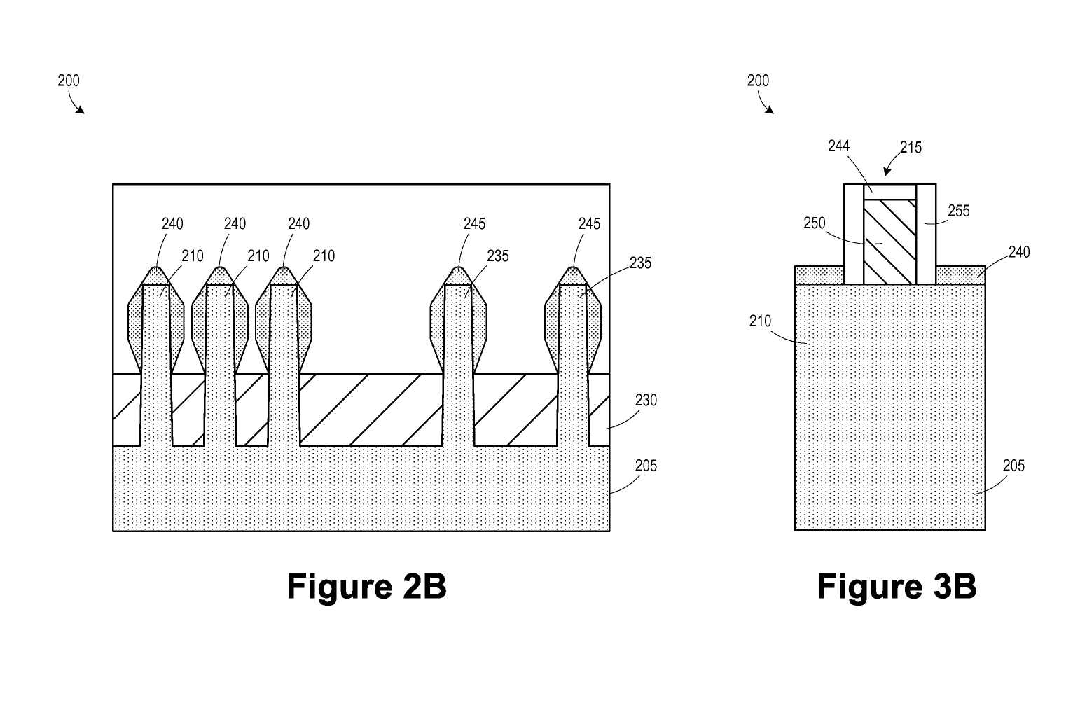

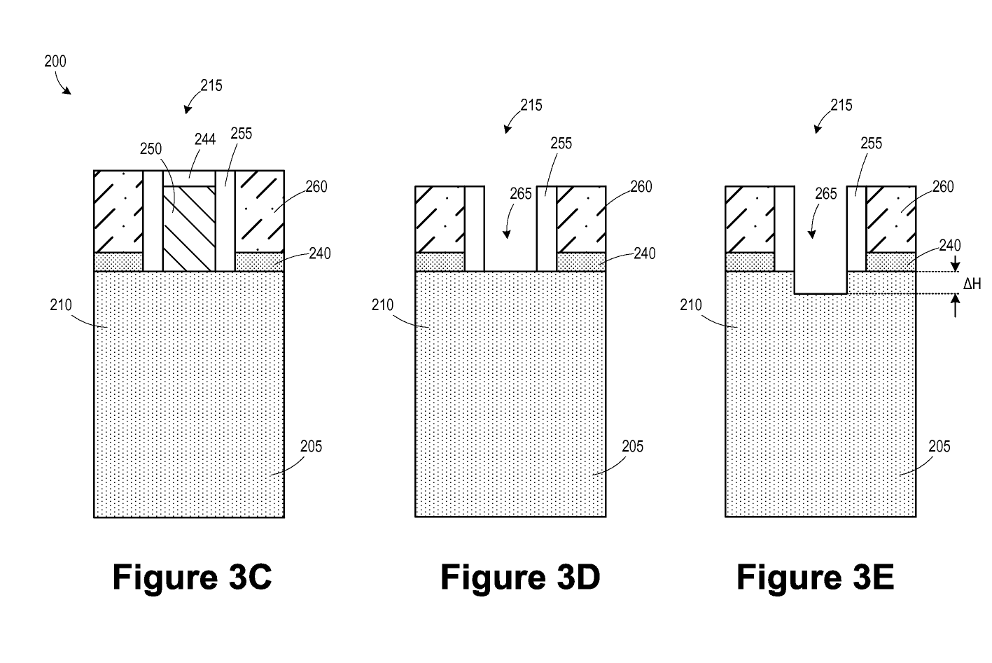

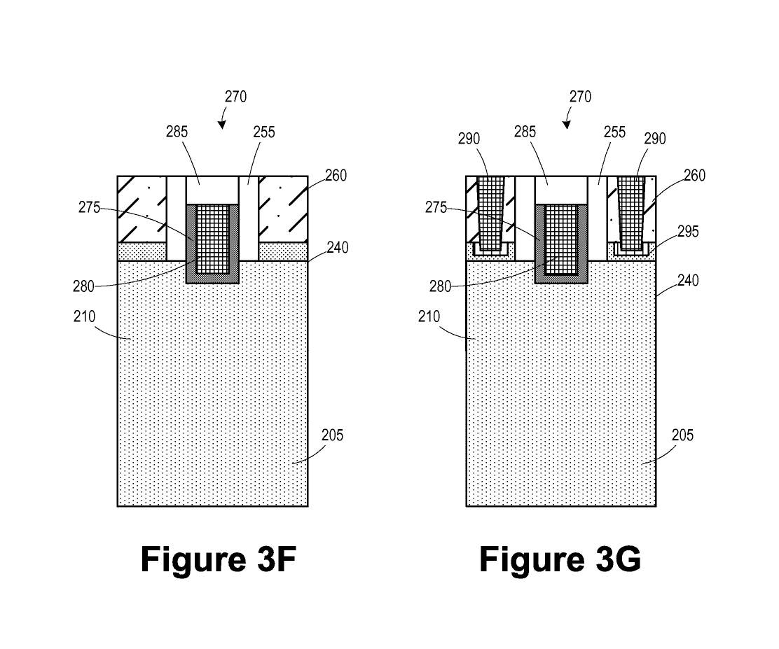

FIGS. 2A-2B and 3A-3G illustrate various methods for forming a finFET device 200. FIGS. 2A-2B show a cross-sectional view (in the gate width direction of the device 200) of densely spaced fins 210 and remote fins 235 defined in a substrate 205 with an isolation structure 230 formed therebetween. FIGS. 3A-3G illustrate a cross-sectional view of the device 200 taken through the long axis of one of the fins 210 in a direction corresponding to the gate length direction of the device 200 (rotated 90 degrees with respect to the view of FIGS. 2A-2B). A placeholder gate electrode structure 215 is depicted in FIGS. 3A-3G. The transistor devices depicted herein may be either NMOS or PMOS transistors. Additionally, various doped regions, e.g., halo implant regions, well regions and the like, may be formed, but are not depicted in the attached drawings. The substrate 205 may have a variety of configurations, such as the depicted bulk silicon configuration. The substrate 205 may also have a silicon-on-insulator (SOI) configuration that includes a bulk silicon layer, a buried insulation layer and an active layer, wherein semiconductor devices are formed in and above the active layer. The substrate 205 may be formed of silicon or silicon germanium or it may be made of materials other than silicon, such as germanium. Thus, the terms “substrate” or “semiconductor substrate” should be understood to cover all semiconducting materials and all forms of such materials. The substrate 205 may have different layers. For example, the fins 210, 235 may be formed in a process layer formed above the base layer of the substrate.

In one illustrative embodiment, a replacement gate technique is used to form the finFET device 200, and the placeholder gate electrode structure 215 is illustrated prior to the formation of the replacement gate structure. The placeholder gate electrode structure 215 includes a sacrificial placeholder material 250, such as polysilicon, and a gate insulation layer (not separately shown), such as silicon dioxide. Also depicted is an illustrative gate cap layer 244 and sidewall spacers 255, both of which are made of a material such as silicon nitride.

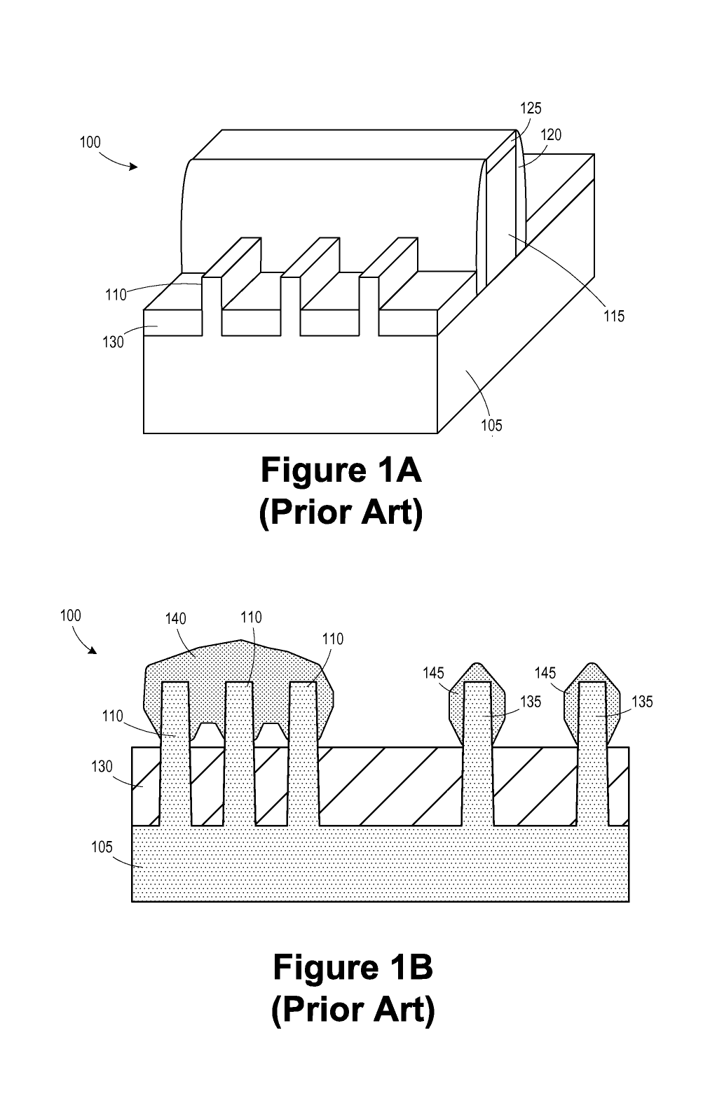

As compared to the prior art device shown in FIG. 1A, the fins 210, 235 have an increased height above the horizontal surface of the substrate 205 in relation to the corresponding height of the fins 110, 135. At the point in the process flow, the fins 210, 235 may be doped with an n-type or p-type dopant to define source/drain regions of the finFET device 200.

FIGS. 2B and 3B illustrate the finFET device 200 after an epitaxial growth process was performed to form epi material on the tip portions of the fins 210, 235 in the source/drain regions of the device 200. Due to the increased height, and the resulting increase in the amount of tapering, the epitaxial growth does not result in a merged epi source/drain region above the densely-spaced fins 210, but rather, discrete epi structures 240 are formed above the densely-spaced fins 210 and discrete epi structures 245 are formed above the isolated fins 235. Even if the epi structures 240 were to merge slightly, the height difference as compared to the epi structures 245 would not be significant. The epi material may be a strain-inducing material, such as silicon germanium or silicon carbon, formed on a silicon fin 210, 235 or silicon formed on a silicon germanium or silicon carbon fin 210, 235. The epi material 240, 245 may be doped in-situ or an implantation process may be performed to dope the epi material 240, 245 in the source/drain regions of the finFET device 200. The gate cap layer 244 and the spacers 255 shield a portion of the fins 210, 235 in a channel region of the finFET device 200 during the epi growth process. In one embodiment, the fins 210, 235 may not have been doped prior to the epi growth process. An implantation process may be performed after the epi growth process to dope both the fins 210, 235 and the epi material 240, 245. If a lightly doped source/drain region is desired, an implant process may be performed on the fins 210, 235 after forming the placeholder material 250, but prior to forming the spacers 255.

Following the epi growth process, an interlayer dielectric layer 260 is formed above the finFET device 200 and planarized (e.g., by a CMP process) to remove the gate cap layer 244 and thereby expose a top surface of the placeholder material 250, as shown in FIG. 3C. An exemplary material for the interlayer dielectric layer 260 is silicon dioxide or a low-k dielectric material (k value less than about 3.5). Other layers of material, such as a stress-inducing contact etch stop layer and the like, may be present but are not depicted in the attached drawings.

The placeholder material 250 and the sacrificial gate insulation layer is removed to expose a channel region fin portion 265, as shown in FIG. 3D. The channel region fin portion 265 is recessed in FIG. 3E using a wet or dry etch process to reduce its height compared to the fin portions in the source/drain regions prior to performing the epitaxial growth process, as denoted by ΔH in FIG. 3E. This recession reduces the fin height in the channel regions to compensate for the additional height added to the fins to avoid epi merger in the source/drain regions during the epi growth process. The value of ΔH may vary depending on the particular application. For example, with a fin 210, 235 height of about 40-70 nm, the recessing can be about 20 nm.

As shown in FIG. 3F, a replacement gate structure 270 is formed above the recessed channel region fin portion 265. The replacement gate structure 270 includes a gate insulation layer 275 formed above the recessed channel region fin portion 265, a conductive gate electrode 280, and an insulating cap layer 285. The gate insulation layer 275 may be comprised of a variety of different deposited or thermally grown materials, such as, for example, silicon dioxide, a so-called high-k (k greater than 10) insulation material (where k is the relative dielectric constant), such as hafnium oxide, etc. The conductive gate electrode 280 may include one or more layers, such as one or more layers of exemplary materials, TiN, TiAlN, TiC, TaN, TaC, TaCN or W. After the materials are formed in the gate cavity, a planarization process may be performed relative to the layer 260. Thereafter, an etch-back process may be performed to recess the material within the gate cavity so as to make room for a cap layer 285. The cap layer 285 (e.g., silicon nitride) may be formed by a performing a deposition process and a subsequent planarization process (e.g., CMP).

As shown in FIG. 3G, contacts 290 of the finFET device 200 are formed in the interlayer dielectric layer 260 to interface with the underlying source/drain regions defined by the fins 210 and the epi material 240. Optionally, a silicide layer 295 may be defined in the epi material 240 prior to depositing the fill material by depositing a metal layer after etching the contact opening, reacting the metal layer with the epi material 240 and removing unreacted portions of the metal layer. Exemplary contact materials include one or more layers of Ti, TiSi, TiN, TaN, WN, W, Ru, Co or Al.

The methods described herein, including forming increased height fins 210, 235 and recessing the fins in channel regions, reduces the likelihood of source/drain epi overfill, thereby providing uniform raised source/drain height throughout densely-spaced regions and isolated regions.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method, comprising:
forming at least one fin in a semiconductor substrate;
forming a sacrificial gate structure around a first portion of said at least one fin;
forming sidewall spacers adjacent said sacrificial gate structure, said sacrificial gate structure and said spacers exposing a second portion of said at least one fin;
forming an epitaxial material on said exposed second portion of said at least one fin;
performing at least one process operation so as to remove said sacrificial gate structure and thereby define a gate cavity between said spacers that exposes said first portion of said at least one fin;
recessing said first portion of said at least one fin to a first height less than a second height of said second portion of said at least one fin; and
forming a replacement gate structure within said gate cavity above said recessed first portion of said at least one fin.

2. The method of claim 1, further comprising:
forming a dielectric material above said epitaxial material;
forming contact openings in said dielectric material to expose said epitaxial material; and
filling said contact openings with a conductive material.

3. The method of claim 2, wherein said conductive material comprises a metal.

4. The method of claim 2, further comprising forming a silicide material on said exposed epitaxial material prior to filling said contact openings with said conductive material.

5. The method of claim 1, wherein forming said at least one fin comprises forming a plurality of fins, and forming said epitaxial material comprises forming a discrete epitaxial material structure on said exposed second portion of each of said fins not covered by said sacrificial gate structure and said spacers.

6. The method of claim 1, wherein forming said replacement gate electrode structure comprises:
forming a dielectric layer above said second portion of said at least one fin; and
forming a conductive material above said dielectric layer.

7. The method of claim 6, wherein forming said dielectric layer comprises forming a high-k dielectric material.

8. The method of claim 1, wherein said epitaxial material comprises a strain-inducing material.

9. The method of claim 8, wherein said strain-inducing material comprises silicon germanium.

10. The method of claim 1, wherein forming said sacrificial gate structure comprises:
forming a polysilicon layer; and
forming an insulating cap layer above said polysilicon layer.

11. A fin field effect transistor, comprising:
at least one fin having a first height;
epitaxial material disposed on a tip portion of said at least one fin in source/drain regions of said fin;
a channel region of said at least one fin defined between said source and drain regions and having a second height less than said first height; and
a gate electrode structure formed above said channel region.

12. The transistor of claim 11, further comprising:
a dielectric material formed above said source/drain regions;
contacts defined in said dielectric material to contact said epitaxial material.

13. The transistor of claim 12, wherein said contacts comprise a metal material.

14. The transistor of claim 12, further comprising silicide material formed on surface portions of said epitaxial material of said source/drain regions and interfacing with said contacts.

15. The transistor of claim 11, further comprising a plurality of fins, wherein said epitaxial material comprises a discrete epitaxial material structure on each of said fins.

16. The transistor of claim 11, wherein said gate electrode structure comprises:
a dielectric layer disposed above said channel region; and
a conductive material formed above said dielectric layer.

17. The transistor of claim 16, wherein said dielectric layer comprises a high-k dielectric material.

18. The transistor of claim 16, wherein said gate electrode structure comprises an insulating cap layer formed above said conductive material.

19. The transistor of claim 11, wherein said epitaxial material comprises a strain-inducing material.

20. The transistor of claim 19, wherein said strain-inducing material comprises silicon germanium.
